(19) United States
(12) Patent Application Publication
(10) Pub. No.: US 2025/0072168 A1
(43) Pub. Date: Feb. 27, 2025

(54) LIGHT-EMITTING DEVICE

(71) Applicant: NICHIA CORPORATION, Anan-shi (JP)

(72) Inventor: Hiroaki KAGEYAMA, Tokushima-shi (JP)

(73) Assignee: NICHIA CORPORATION, Anan-shi (JP)

(21) Appl. No.: 18/783,052

(22) Filed: Jul. 24, 2024

(30) Foreign Application Priority Data
Aug. 24, 2023 (JP) 2023-136504

(51) Int. Cl. H01L 33/20; H01L 25/075

(52) U.S. Cl. CPC H01L 33/20; H01L 25/0753

(57) ABSTRACT

A light-emitting device includes a wiring substrate and a plurality of light-emitting elements arrayed on the wiring substrate along a first direction and each having a rectangular shape. The light-emitting elements each include a first portion, and a plurality of second portions disposed on either side of the first portion in the first direction. The first portion includes a first semiconductor layered body and an electrode. The second portions each include a second semiconductor layered body, and a reflective layer connected to the second semiconductor layered body. The first portion includes a first length section and a second length section. In the first length section, a length of the first semiconductor layered body in the first direction is a first length. In the second length section, a length of the first semiconductor layered body in the first direction is a second length shorter than the first length.

### CROSS-REFERENCE TO RELATED APPLICATION

This application claims priority to Japanese Patent Application No. 2023-136504, filed on Aug. 24, 2023, the disclosure of which is hereby incorporated by reference in its entirety.

### TECHNICAL FIELD

Embodiments relate to a light-emitting device.

### BACKGROUND

A light-emitting device in which a plurality of light-emitting elements are mounted on a wiring substrate has been developed as a light source of a vehicle head lamp. In such a light-emitting device, by independently controlling each of the light-emitting elements, a desired light emission pattern can be achieved through the entire light-emitting device (See for example, Japanese Patent Publication No. 2021-180113).

### SUMMARY

An object of an embodiment is to increase a luminance difference between a light-emitting portion and a non-light-emitting portion in a light-emitting device including a plurality of light-emitting portions.

A light-emitting device according to an embodiment includes a wiring substrate, and a plurality of light-emitting elements arrayed on the wiring substrate along a first direction and each having a rectangular shape in a top view. The light-emitting elements each include a first portion and a plurality of second portions disposed on either side of the first portion in the first direction. The first portion includes a first semiconductor layered body and an electrode connected to the first semiconductor layered body. The second portions each include a second semiconductor layered body and a reflective layer connected to the second semiconductor layered body. The first portion includes a first length section and a second length section. In the first length section, a length of the first semiconductor layered body in the first direction is a first length. In the second length section, a length of the first semiconductor layered body in the first direction is a second length. The second length is shorter than the first length.

According to an embodiment, in a light-emitting device including a plurality of light-emitting portions, a luminance difference between the light-emitting portion and a non-light-emitting portion can be increased.

### BRIEF DESCRIPTION OF DRAWINGS

FIG. 1 is a schematic perspective view of a light-emitting device according to a first embodiment.

FIG. 2 is a schematic cross-sectional view taken along a line II-II in FIG. 1.

FIG. 3 is a schematic top view illustrating a region III illustrated in FIG. 1.

FIG. 4 is a schematic bottom view illustrating the light-emitting element and a light-transmissive member according to the first embodiment.

FIG. 5 is a schematic cross-sectional view taken along a line V-V in FIG. 4.

FIG. 6 is a schematic cross-sectional view illustrating operations according to the first embodiment.

FIG. 7 is a schematic top view illustrating a light-emitting element according to a first modified example of the first embodiment.

FIG. 8 is a schematic top view illustrating a light-emitting element according to a second modified example of the first embodiment.

FIG. 9 is a schematic perspective view illustrating a light-emitting device according to a third modified example of the first embodiment.

FIG. 10 is a schematic perspective view illustrating a light-emitting device according to a fourth modified example of the first embodiment.

FIG. 11 is a schematic top view illustrating a light-emitting device according to a second embodiment.

FIG. 12 is a schematic bottom view illustrating the light-emitting element and a light-transmissive member according to the second embodiment.

FIG. 13 is a schematic cross-sectional view taken along a line XIII-XIII in FIG. 12.

FIG. 14 is a schematic top view illustrating operations according to the second embodiment.

### DETAILED DESCRIPTIONS

### First Embodiment

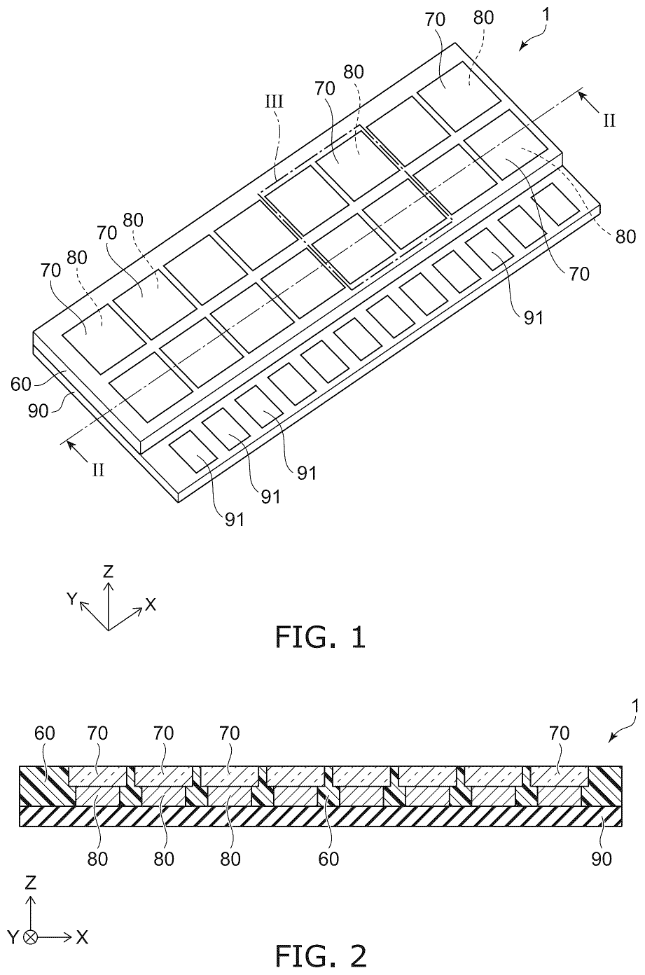

FIG. 1 is a schematic perspective view illustrating a light-emitting device according to a present embodiment.

FIG. 2 is a schematic cross-sectional view taken along a line II-II in FIG. 1.

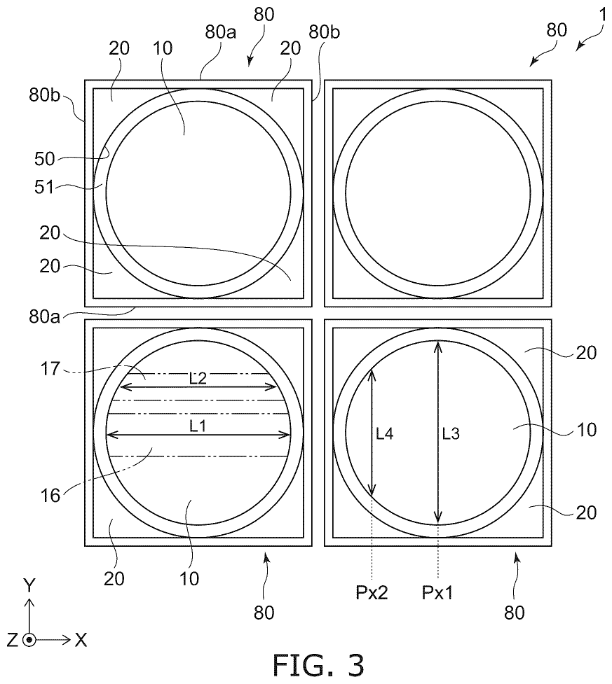

FIG. 3 is a schematic top view illustrating a region III illustrated in FIG. 1.

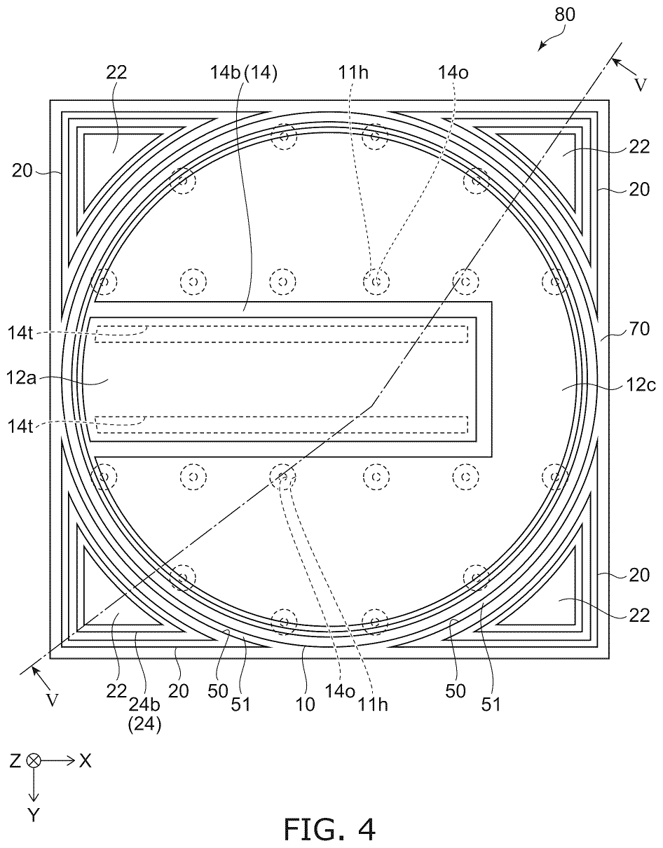

FIG. 4 is a schematic bottom view illustrating the light-emitting element and a light-transmissive member according to the present embodiment.

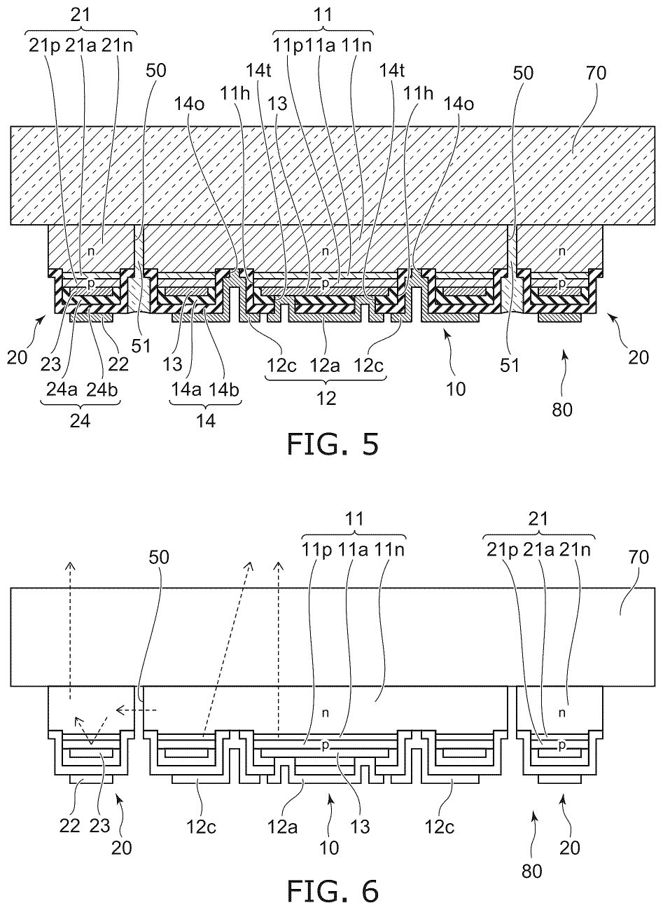

FIG. 5 is a schematic cross-sectional view taken along a line V-V in FIG. 4.

In FIGS. 1 to 3, the configuration of the light-emitting element is schematically illustrated. In FIG. 3, the light-transmissive member to be described later is not illustrated, and only a semiconductor layered body of the light-emitting element is illustrated.

Note that all the drawings are illustrated schematically and may be exaggerated or simplified as appropriate. Further, even in the case of the same component, a dimensional ratio may be different between the drawings. The same applies to other schematic drawings described below.

As illustrated in FIGS. 1 to 3, a light-emitting device 1 according to the present embodiment is provided with a wiring substrate 90 and a plurality of light-emitting elements 80. The plurality of light-emitting elements 80 are arrayed along a first direction X on the wiring substrate 90. A shape of each of the light-emitting elements 80 in a top view is rectangular.

Hereinafter, two directions in which the light-emitting elements 80 are arrayed are referred to as the “first direction X” and a “second direction Y.” A thickness direction from the wiring substrate 90 toward the light-emitting elements 80 is referred to as a “third direction Z.” The first direction X, the second direction Y, and the third direction Z are orthogonal to each other. In the example illustrated in FIG. 1, the shape of the wiring substrate 90 is a rectangular plate shape, the first direction X is the longitudinal direction of the wiring substrate 90, and the second direction Y is the width direction of the wiring substrate 90. Further, the third direction Z is also referred to as an “upward direction,” and an opposite direction thereof is also referred to as a “downward direction.” However, these expressions are used for convenience, and are unrelated to a gravity direction. Further, a “top view” refers to viewing along the third direction Z.

In the present embodiment, the plurality of light-emitting elements 80 are arrayed in a matrix along the first direction X and the second direction Y. For example, roughly 10 to 200 light-emitting elements 80 are provided. In the example illustrated in FIGS. 1 to 3, 16 light-emitting elements 80 are provided in a matrix of two rows and eight columns. A distance between the light-emitting elements 80 is, for example, 50 μm or less. In a top view, the light-emitting element 80 has a pair of sides 80a extending in the first direction X and a pair of sides 80b extending in the second direction Y orthogonal to the first direction X.

The plurality of light-emitting elements 80 provided in the light-emitting device 1 have the same shape and configuration. However, the plurality of light-emitting elements 80 need to be arrayed substantially in a matrix at equal intervals as a whole, and light-emitting elements having different shapes may be included. For example, a light-emitting element having a rectangular shape in a top view may be included. Further, when the plurality of light-emitting elements 80 are arrayed substantially in a matrix as a whole, there may be a region in which the light-emitting elements are partially not arrayed.

The wiring substrate 90 includes a base material formed of an insulating material and wiring disposed on the base material. A plurality of pads 91, which are connected to the light-emitting elements 80, are provided on the upper surface of the wiring substrate 90, that is, on the surface on which the light-emitting elements 80 are disposed. As an example, the pads 91 are arrayed in one row along an edge extending in the longitudinal direction of the wiring substrate 90. In the light-emitting device 1, a current is supplied from the outside via the plurality of pads 91, and some or all of the plurality of light-emitting elements 80 can be individually driven.

The light-emitting device 1 may be further provided with a light-transmissive member 70 and a covering member 60. The light-transmissive member 70 has a lower surface on which light emitted from the light-emitting element 80 is incident, and an upper surface which is a surface opposite to the lower surface and which constitutes a light-emitting surface of the light-emitting device 1. The light-transmissive member 70 is provided, for example, for each of the light-emitting elements 80, and is disposed on the upper surface of the light-emitting element 80. In the light-transmissive member 70, for example, phosphor particles are contained in a base material formed of a light-transmissive material. The covering member 60 is disposed between the adjacent light-emitting elements 80. The covering member 60 is formed of an insulating material. For example, particles of a light-reflective substance are contained in a base material formed of a light-transmissive material. The covering member 60 is, for example, a member having a white appearance color. The covering member 60 may be disposed between the adjacent light-transmissive members 70 and furthermore be disposed on the outer periphery of the plurality of light-emitting elements 80 and the plurality of light-transmissive members 70 as a whole.

Each of the light-emitting elements 80 includes a first portion 10 and a plurality of second portions 20. In the example illustrated in FIG. 3, one first portion 10 and four second portions 20 are provided in each of the light-emitting elements 80. In a top view, the first portion 10 is positioned at the center of the light-emitting element 80. That is, the center of the light-emitting element 80 is positioned in the first portion 10. The center of the light-emitting element 80 is an intersection of diagonal lines. For example, the top view shape of the first portion 10 is circular. In this case, the center of the first portion 10 preferably coincides with the center of the light-emitting element 80 in a top view. The second portions 20 are respectively positioned, one by one, at four corners of the light-emitting element 80 having the rectangular shape in a top view.

As illustrated in FIGS. 4 and 5, the first portion 10 includes a first semiconductor layered body 11, a reflective layer 13, an insulating layer 14, and an electrode 12. Each of the second portions 20 includes a second semiconductor layered body 21, a reflective layer 23, an insulating layer 24, and an electrode 22.

The first semiconductor layered body 11 is formed using gallium nitride (GaN), for example. The first semiconductor layered body 11 includes a p-type layer 11p, a light-emitting layer 11a disposed on the p-type layer 11p, and an n-type layer 11n disposed on the light-emitting layer 11a.

In the first portion 10, the reflective layer 13 is disposed on the lower surface of the first semiconductor layered body 11 (i.e., the lower surface of the p-type layer 11p). As the reflective layer 13, for example, a metal material having conductivity and good light reflectivity is used. For example, the reflective layer 13 is a metal layer containing aluminum (Al) or silver (Ag), which has good light reflectivity. Thus, the light emitted from the light-emitting layer 11a and traveling downward can be reflected by the reflective layer 13 and exit from above (i.e., from the side of a surface on the n-type layer side in the first semiconductor layered body 11).

The electrode 12 is connected to the first semiconductor layered body 11 via the reflective layer 13. The electrode 12 includes an anode electrode 12a and a cathode electrode 12c. Note that in this specification, “connected” refers to being electrically connected.

A plurality of holes 11h are formed in the surface on the p-type layer 11p side of the first semiconductor layered body 11. The hole 11h extends through the p-type layer 11p and the light-emitting layer 11a and reaches the n-type layer 11n. A portion of a bottom surface of the n-type layer 11n at the hole 11h is exposed from the p-type layer 11p and the light-emitting layer 11a. The reflective layer 13 is disposed on the surface on the p-type layer 11p side of the first semiconductor layered body 11 in a region excluding the holes 11h, and is in contact with the p-type layer 11p.

The insulating layer 14 is disposed on the lower surface of the reflective layer 13, and on the lower surface side of the first semiconductor layered body 11. Specifically, the insulating layer 14 is disposed in a region of the lower surface of the first semiconductor layered body 11 excluding the holes 11h. A trench 14t is formed in the insulating layer 14. The trench 14t extends along the first direction X in a top view. A portion of a bottom surface of the reflective layer 13 at the trench 14t is exposed from the insulating layer 14. The insulating layer 14 is also disposed on lateral surfaces defining the holes 11h. In the hole 11h, an opening portion 140 is formed through the insulating layer 14. A portion of the n-type layer 11n is exposed from the insulating layer 14 at the opening portion 140. The electrode 12 and the first semiconductor layered body 11 are connected via the opening portion 140 of the insulating layer 14.

Here, the insulating layer 14 includes an insulating layer 14a that is disposed on the surface on the p-type layer 11p side and covers the reflective layer 13, and an insulating layer 14b that covers the insulating layer 14a and covers the lateral surfaces defining the hole 11h. The insulating layer 14a is formed of silicon nitride (SiN), for example. The insulating layer 14b is formed of silicon oxide (SiO), for example.

In a top view, among the plurality of holes 11h, some of the holes 11h are arranged along the trench 14t, and others of the holes 11h are arrayed along the outer edge of the first semiconductor layered body 11.

In a top view, the shape of the anode electrode 12a is an elongated shape, and the longitudinal direction thereof is the first direction X and the width direction thereof is the second direction Y, for example. One short side of the anode electrode 12a reaches an edge of the first semiconductor layered body 11, and the other short side and the pair of long sides of the anode electrode 12a are distance apart from the edge of the first semiconductor layered body 11. The anode electrode 12a is in contact with the portion of the reflective layer 13 exposed at the trench 14t, and is disposed at a position distance apart from the hole 11h. Thus, the anode electrode 12a is connected to the p-type layer 11p of the first semiconductor layered body 11 via the trench 14t and the reflective layer 13. In the light-emitting device 1, the anode electrode 12a is connected to the wiring of the wiring substrate 90.

In a top view, the cathode electrode 12c surrounds the anode electrode 12a from three directions. The cathode electrode 12c is distance apart from the anode electrode 12a and the reflective layer 13. The cathode electrode 12c is in contact with the portion of the bottom surface of the n-type layer exposed at the hole 11h and is disposed at a position distance apart from the trench 14t. Thus, the cathode electrode 12c is connected to the n-type layer 11n of the first semiconductor layered body 11 via the hole 11h. In the light-emitting device 1, the cathode electrode 12c is connected to the wiring of the wiring substrate 90.

The layered structure and the composition of each of portions of the second portion 20 are basically the same as those of the first portion 10. That is, the layered structure and the composition of each of the portions of the second semiconductor layered body 21 of the second portion 20 are substantially the same as the layered structure and the composition of each of the portions of the first semiconductor layered body 11 of the first portion 10. For example, a p-type layer 21p, a light-emitting layer 21a, and an n-type layer 21n formed using GaN are layered. “Substantially the same” means, for example, that design values are the same, and means that an inevitable error caused by a variation in a manufacturing process or the like is not recognized as a difference.

The second semiconductor layered body 21 is adjacent to the first semiconductor layered body 11, via a gap 50. In a top view, the shape of the gap 50 is an arc shape along the outer edge of the first semiconductor layered body 11. In the light-emitting device 1, the covering member 60 is not disposed in the gap 50. A light-transmissive resin may be disposed in the gap 50 or an air layer may be formed in the gap 50. FIG. 5 illustrates an example in which a light-transmissive resin 51 is disposed. The light-transmissive resin 51 is, for example, an adhesive. Thus, the second semiconductor layered body 21 is electrically separated from and optically coupled to the first semiconductor layered body 11.

Further, a reflective layer 23 is disposed on the lower surface of the second semiconductor layered body 21. The composition and thickness of the reflective layer 23 are substantially the same as the composition and thickness of the reflective layer 13. The second portion 20 further includes insulating layers 24a and 24b. The compositions and thicknesses of the insulating layers 24a and 24b are substantially the same as those of the insulating layers 14a and 14b, respectively. The insulating layer 24a is disposed on the lower surface of the second semiconductor layered body 21 so as to cover the reflective layer 23, and the insulating layer 24b is disposed on the lower surface of the second semiconductor layered body 21 so as to cover the insulating layer 24a.

The second portion 20 may further include an electrode 22. The electrode 22 is disposed on the lower surface of the insulating layer 24b. In the present embodiment, the electrode 22 is insulated from the second semiconductor layered body 21 by the insulating layers 24a and 24b. In the light-emitting device 1, the electrode 22 may be or does not have to be connected to the wiring of the wiring substrate 90. Because the electrode 22 is not connected to the second semiconductor layered body 21, power is not supplied to the second semiconductor layered body 21 via the electrode 22.

As illustrated in FIG. 3, the first portion 10 includes a first length section 16 and a second length section 17 having different lengths in the first direction X of the first semiconductor layered body 11. In the first length section 16, the length of the first semiconductor layered body 11 in the first direction X is a first length L1. In the second length section 17, the length of the first semiconductor layered body 11 in the first direction X is a second length L2. The second length L2 is shorter than the first length L1. That is, L2<L1. Here, the first length L1 is the maximum length of the first semiconductor layered body 11 in the first direction X. That is, the first length section 16 is a region in which the length of the first semiconductor layered body 11 in the first direction X is the first length L1. The second length section 17 is a region in which the length of the first semiconductor layered body 11 in the first direction X is the second length L2 shorter than the first length L1 (that is, a region excluding the first length section).

For example, the first length section 16 is located at the center of the first portion 10 in the second direction Y. In this case, as illustrated in FIG. 3, when the shape of the first portion 10 is circular in a top view, the first length L1 is the diameter of the circle, and is the maximum length of the first semiconductor layered body 11 in the first direction X. In the first semiconductor layered body 11, a boundary between the first length section 16 and the second length section 17 cannot be visually recognized.

Further, a third length L3 in the second direction Y at a first position Px1 in the first direction X of the first semiconductor layered body 11 is longer than a fourth length L4 in the second direction Y at a second position Px2 in the first direction X of the first semiconductor layered body 11. That is, L3>L4. For example, the first position Px1 is the center of the first portion 10 in the first direction X. In this case, when the shape of the first portion 10 is circular in a top view, the third length L3 is the diameter of the circle, and is the maximum length of the first semiconductor layered body 11 in the second direction Y. The fourth length L4 is the length of the first semiconductor layered body 11 in the second direction Y in a region other than the diameter.

When the shape of the first portion 10 is circular in a top view, the first length L1 is the maximum length of the first semiconductor layered body 11 in the first direction X, and the third length L3 is the maximum length of the first semiconductor layered body 11 in the second direction Y, the first length L1 and the third length L3 are the diameter of the first portion 10 and are substantially equal to each other. That is, L1≈L3.

Next, operations of the light-emitting device according to the present embodiment will be described.

FIG. 6 is a cross-sectional view illustrating operations according to the present embodiment. In FIG. 6, examples of optical paths of the light-emitting element 80 are indicated by broken lines.

As illustrated in FIG. 6, when power is supplied to the light-emitting element 80 via the wiring substrate 90, in the first portion 10, a positive potential is applied from the anode electrode 12a to the p-type layer 11p via the reflective layer 13, and a negative potential is applied from the cathode electrode 12c to the n-type layer 11n. In this way, the light-emitting layer 11a emits light. The light emitted from the light-emitting layer 11a propagates through the first semiconductor layered body 11, and most of the light exits from the first semiconductor layered body 11 to the outside of the light-emitting device 1 through the light-transmissive member 70. At this time, part of the light emitted from the light-emitting layer 11a is reflected by the reflective layer 13, the anode electrode 12a, or the cathode electrode 12c.

On the other hand, the light-emitting layer 21a of the second semiconductor layered body 21 does not emit light because the second semiconductor layered body 21 is not connected to the wiring of the wiring substrate 90 and is not supplied with power. However, a part of the light emitted from the light-emitting layer 11a enters the second semiconductor layered body 21 via the gap 50, and exits from the second semiconductor layered body 21 to the outside of the light-emitting device 1 through the light-transmissive member 70. At this time, a part of the light entering the second semiconductor layered body 21 is reflected by the reflective layer 23.

As a result, from the outside of the light-emitting device 1, it appears that the first portion 10 of the light-emitting element 80 that is lit emits light strongly and the second portion 20 emits light weakly. Therefore, it is possible to reduce the likelihood of occurrence of a dark line between the adjacent light-emitting elements 80.

In the present embodiment, because the second length L2 of the second length section 17 is shorter than the first length L1 of the first length section 16, the light emitted from the second length section 17 in the first direction X is incident on the second portion 20 of the same light-emitting element 80. Further, because the fourth length L4 is shorter than the third length L3, light emitted in the second direction Y from a portion whose length in the second direction Y is the fourth length L4 is incident on the second portion 20 of the same light-emitting element 80. As a result, most of the light emitted along an XY plane from the lateral surface of the first portion 10 of a given one of the light-emitting elements 80 enters the second portion 20 of the same light-emitting element 80, and exits from this second portion 20 to the outside of the light-emitting device 1 via the light-transmissive member 70.

Accordingly, it is possible to reduce propagation of light from the given light-emitting element 80 to the light-emitting element 80 disposed adjacent to the given light-emitting element 80. For example, when the light-emitting element 80 that is lit and the light-emitting element 80 that is unlit are adjacent to each other, it is possible to reduce the possibility that the light-emitting element 80 that is unlit appears to emit light due to propagation of the light from the light-emitting element 80 that is lit. In this manner, the light-emitting device 1 having good light-emitting properties during partial illumination can be obtained.

Subsequently, an effect of the present embodiment will be described.

According to the present embodiment, because the unlit second portion 20 is disposed near the lit first portion 10 via the gap 50, when the first portion 10 of the given light-emitting element 80 emits light, part of the light propagating from the first portion 10 can exit from the second portion of the same light-emitting element 80. Further, because the shape of the first portion 10 is circular in a top view, the length of the outer edge of the given first portion 10 closest to the portion of the outer edge of the first portion 10 in the adjacent light-emitting element 80 can be shorten, compared to a case in which one side of the rectangle of the first portion 10 having a rectangular shape in a top view faces one side of the rectangle of the first portion 10 having a rectangular shape in a top view of the adjacent light-emitting element 80. In this way, it is possible to reduce light propagation of light emitted from the first portion 10 to the adjacent light-emitting element 80. In other words, it is possible to increase a luminance difference (contrast) between the light-emitting element 80 that is lit and the adjacent light-emitting element 80 that is unlit. In this way, the light-emitting device can exhibit good light-emitting characteristics during partial illumination. Further, because the second portion 20 emits light weakly, a light-emitting region is widened, and it is possible to suppress a dark line from being visually recognized between the adjacent light-emitting elements 80 when these light-emitting elements 80 emit light.

Further, the reflective layer 23 provided on the second semiconductor layered body 21 upwardly reflects part of the light incident on the second semiconductor layered body 21 from the first semiconductor layered body 11. Thus, the light extraction efficiency of the light-emitting element 80 that is lit can be improved.

Furthermore, in the present embodiment, because the light-transmissive member 70 is provided for each of the light-emitting elements 80, the light emitted from the first portion 10 and the light emitted from the second portion 20 are incident on the light-transmissive member 70. Therefore, the boundary between the first portion 10 and the second portion 20 is not easily recognized when viewed from the outside of the light-emitting device 1. On the other hand, the boundary between the light-emitting elements 80 adjacent to each other is also the boundary between the light-transmissive members 70 adjacent to each other, and thus is easily recognized. This also improves the contrast between the light-emitting elements 80.

Furthermore, according to the present embodiment, because it is not necessary to provide an excessive interval between the light-emitting elements 80 in order to improve the contrast, the light-emitting device 1 can be miniaturized. As a result, the degree of freedom of design is improved in an apparatus to which the light-emitting device 1 is mounted. For example, when the light-emitting device 1 is used as the light source of a vehicle head lamp, the degree of freedom in design of the head lamp is improved.

### First Modified Example of First Embodiment

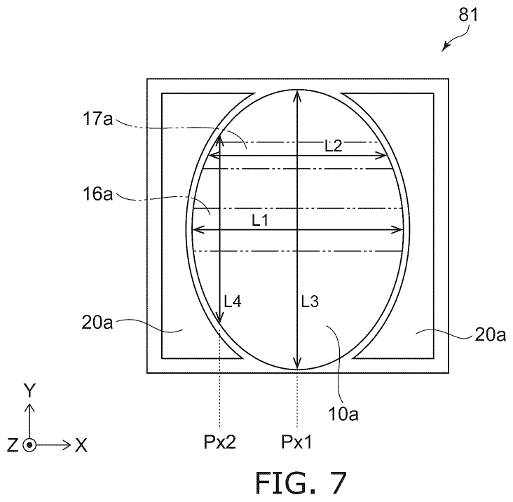

FIG. 7 is a schematic top view illustrating a light-emitting element according to a present modified example.

In FIG. 7, a light-transmissive member is not illustrated, and only a semiconductor layered body of the light-emitting element is illustrated.

As illustrated in FIG. 7, in a light-emitting element 81 according to the present modified example, the shape of a first portion 10a is elliptical in a top view. The major axis direction of the first portion 10a is the second direction Y, and the minor axis direction thereof is the first direction X. Two second portions 20a are provided, and one of the second portions 20a is disposed on each of both sides of the first portion 10a in the first direction X in a top view.

Also in the present modified example, the first portion 10a includes a first length section 16a and a second length section 17a. The first length L1 of the first length section 16a in the first direction X is longer than the second length L2 of the second length section 17a in the first direction X. Further, the third length L3 in the second direction Y at the first position Px1 at the center of the first portion 10a in the first direction X is longer than the fourth length L4 in the second direction Y at the second position Px2 offset from the center of the first portion 10a in the first direction X. In the present modified example, the first length L1 is shorter than the third length L3. The second portions 20a are disposed on both sides of the first length section 16a in the first direction X.

According to the present modified example, the effects same as or similar to those of the first embodiment can be obtained in the first direction X. The configuration, operation, and effects of the present modified example other than those described above are the same as those of the first embodiment.

### Second Modified Example of First Embodiment

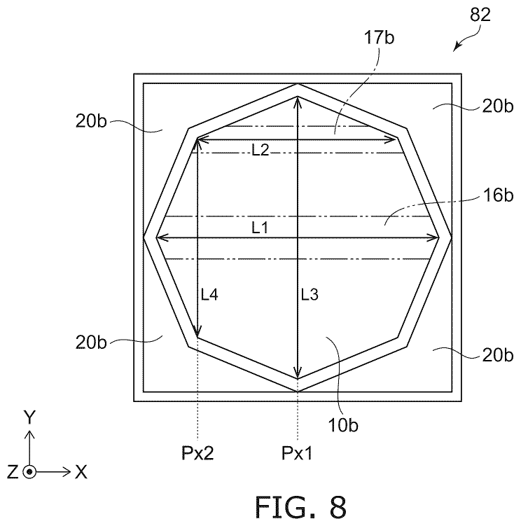

FIG. 8 is a schematic top view illustrating a light-emitting element according to a present modified example.

In FIG. 8, a light-transmissive member is not illustrated, and only a semiconductor layered body of the light-emitting element is illustrated.

As illustrated in FIG. 8, in a light-emitting element 82 according to the present modified example, the shape of a first portion 10b is a polygon in a top view. In a top view, the shape of the first portion 10b preferably has 4n symmetry (n is a positive integer), and is a regular octagon in the example illustrated in FIG. 8. The light-emitting element 82 includes four second portions 20b, which are disposed at four corners of the light-emitting element 82 in a top view.

Also in the present modified example, the first portion 10b includes a first length section 16b and a second length section 17b. The first length L1 of the first length section 16b in the first direction X is longer than the second length L2 of the second length section 17b in the first direction X. Further, the third length L3 in the second direction Y at the first position Px1 at the center of the first portion 10b in the first direction X is longer than the fourth length L4 in the second direction Y at the second position Px2 offset from the center of the first portion 10b in the first direction X. In the present modified example, the first length L1 is substantially the same as the third length L3.

According to the present modified example, the effects same as or similar to those of the first embodiment can be obtained in the first direction X and the second direction Y. The configuration, operation, and effects of the present modified example other than those described above are the same as those of the first embodiment.

### Third Modified Example of First Embodiment

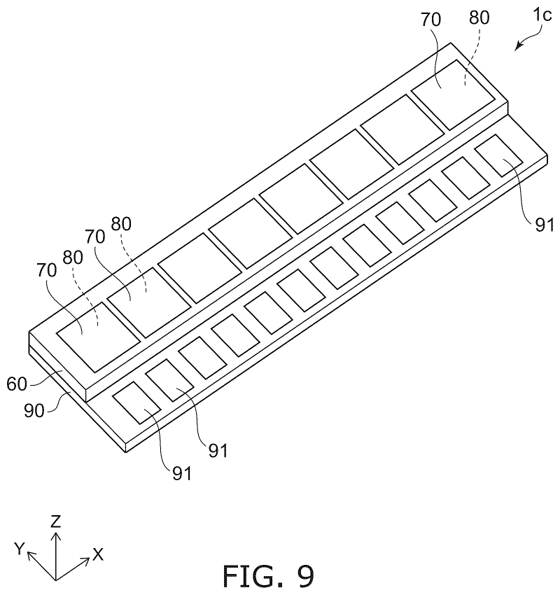

FIG. 9 is a schematic perspective view illustrating a light-emitting device according to a present modified example.

As illustrated in FIG. 9, a light-emitting device 1c according to the present modified example differs from the light-emitting device 1 according to the first embodiment in the number and arrangement of the light-emitting elements 80. In the light-emitting device 1c according to the present modified example, eight light-emitting elements 80 are arrayed in one row along the first direction X. In the present modified example, the configuration of the light-emitting element may be the configuration illustrated in the first modified example described above. The configuration, operation, and effects of the present modified example other than those described above are the same as or similar to those of the first embodiment.

### Fourth Modified Example of First Embodiment

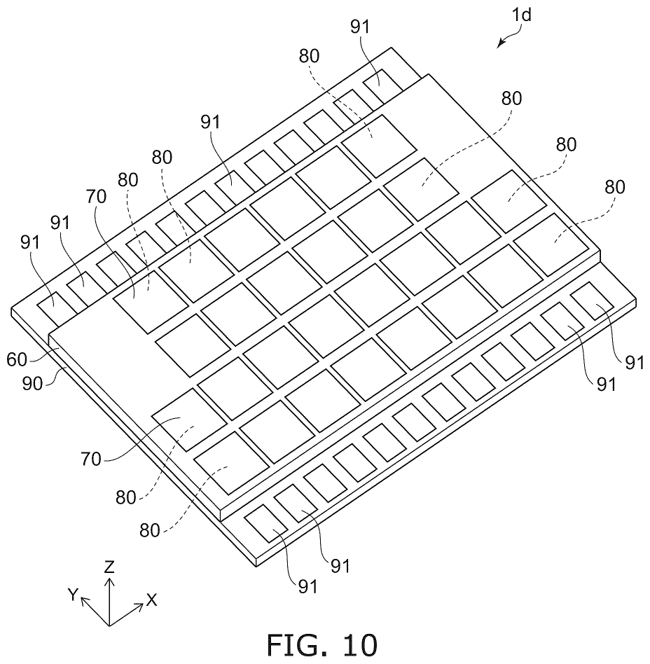

FIG. 10 is a schematic perspective view illustrating a light-emitting device according to a present modified example.

As illustrated in FIG. 10, a light-emitting device 1d according to the present modified example differs from the light-emitting device 1 according to the first embodiment in the number and arrangement of the light-emitting elements 80.

In the light-emitting device 1d according to the present modified example, 28 light-emitting elements 80 are arrayed substantially in a matrix. That is, the light-emitting elements 80 are generally arrayed in a matrix of four rows and eight columns, but there are four sections in which no light-emitting element is arranged. Further, the pads 91 are arrayed in two rows along two edges extending in the first direction X of the wiring substrate 90. The configuration, operation, and effects of the present modified example other than those described above are the same as or similar to those of the first embodiment.

### Second Embodiment

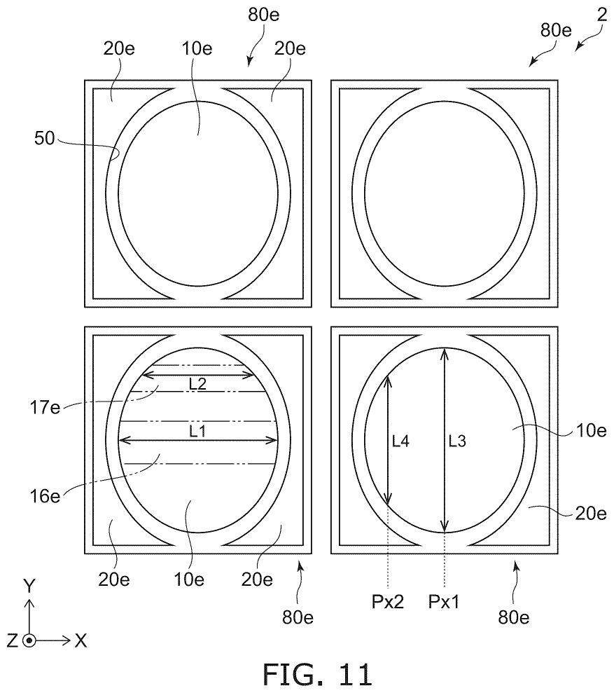

FIG. 11 is a top view illustrating a light-emitting device according to a present embodiment.

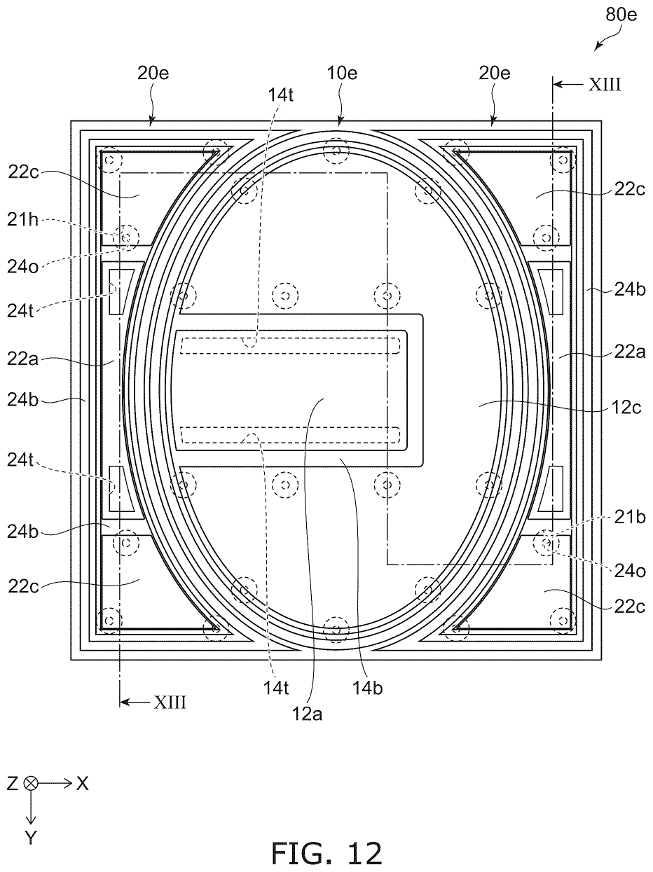

FIG. 12 is a bottom view illustrating a light-emitting element and a light-transmissive member according to the present embodiment.

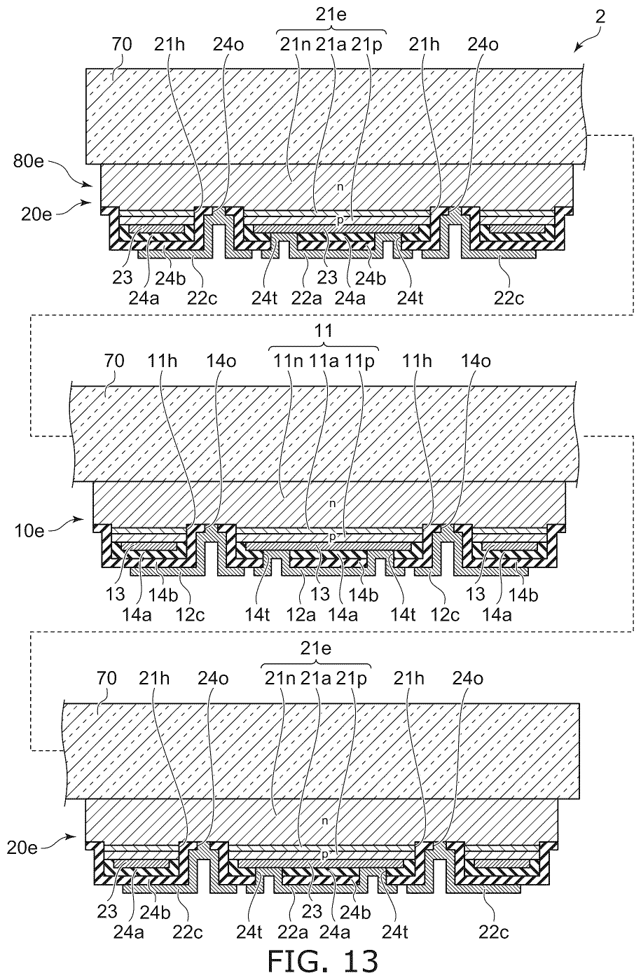

FIG. 13 is a cross-sectional view taken along a line XIII-XIII in FIG. 12.

In FIG. 11, the light-transmissive member 70 is not illustrated, and only the semiconductor layered body of the light-emitting element is illustrated. In FIG. 13, one continuous cross section is divided into three stages for convenience of space on the drawing.

As illustrated in FIG. 11, a light-emitting device 2 according to the present embodiment is different from the light-emitting device 1 according to the first embodiment in the configuration of light-emitting elements 80e. Specifically, the light-emitting element 80e includes one first portion 10e and two second portions 20e, similarly to the light-emitting element 81 according to the first modified example of the first embodiment.

As illustrated in FIGS. 12 and 13, the configuration of the first portion 10e is the same as or similar to the configuration of the first portion 10 according to the first embodiment, except that the overall shape of the first portion 10e is elliptical. In other words, the first portion 10e includes the first semiconductor layered body 11, the anode electrode 12a, the cathode electrode 12c, the reflective layer 13, and the insulating layers 14a and 14b. The first semiconductor layered body 11 includes the p-type layer 11p, the light-emitting layer 11a, and the n-type layer 11n. The p-type layer 11p is connected to the anode electrode 12a via the reflective layer 13, and the n-type layer 11n is connected to the cathode electrode 12c.

The configuration of the second portion 20e partially differs from to the configuration of the second portion 20 according to the first embodiment. The second portion 20e includes an anode electrode 22a and a cathode electrode 22c in addition to a second semiconductor layered body 21e, the reflective layer 23, and the insulating layers 24a and 24b. The anode electrode 22a and the cathode electrode 22c are disposed on the lower surface of the insulating layer 24b. The second semiconductor layered body 21e is distance apart from the first semiconductor layered body 11 via the gap 50.

A plurality of holes 21h are formed in the surface on the p-type layer 21p side of the second semiconductor layered body 21e. The hole 21h extends through the p-type layer 21p and the light-emitting layer 21a and reaches the n-type layer 21n. At the hole 21h, a portion of a bottom surface of the n-type layer 21n is exposed from the p-type layer 21p and the light-emitting layer 21a. The reflective layer 23 is disposed on the surface on the p-type layer 21p side of the second semiconductor layered body 21e in a region excluding the holes 21h, and is in contact with the p-type layer 21p. Some of the plurality of holes 21h are located at both of end portions of the second portion 20e in the second direction Y.

The insulating layer 24a is disposed in a region of the lower surface of the second semiconductor layered body 21e excluding the holes 21h, and covers the reflective layer 23. The insulating layer 24b is disposed on substantially the entire lower surface of the second semiconductor layered body 21e, and covers the reflective layer 23 and the insulating layer 24a. Two opening portions 24t are formed through the insulating layers 24a and 24b. The opening portion 24t extends through the insulating layers 24a and 24b, and a portion of a bottom surface of the reflective layer 23 is exposed from the insulating layers 24a and 24b at the opening portion 24t. The insulating layer 24b is also disposed on the lateral surfaces defining the holes 21h. In the hole 21h, an opening portion 240 is formed through the insulating layer 24b. A portion of a bottom surface of the n-type layer 21n is exposed from the insulating layer 24b at the opening portion 240.

The one anode electrode 22a is provided in each of the second portions 20e. In a top view, the shape of the anode electrode 22a is an elongated shape, the longitudinal direction thereof is the second direction Y, and the width direction thereof is the first direction X. The anode electrode 22a is disposed in a central portion of the second portion 20e in the second direction Y. The anode electrode 22a covers the opening portion 24t and is disposed at a position distance apart from the hole 21h. Thus, the anode electrode 22a is connected to the p-type layer 21p of the second semiconductor layered body 21e via the opening portion 24t and the reflective layer 23. Further, in the light-emitting device 2, the anode electrode 22a is connected to the wiring of the wiring substrate 90.

Two cathode electrodes 22c are provided in each of the second portions 20e. In a top view, the cathode electrodes 22c each have a substantially trapezoidal shape, and are disposed at both end portions of the second portion 20e in the second direction Y. The cathode electrode 22c is distance apart from the anode electrode 22a and the reflective layer 23. The cathode electrode 22c is disposed at a position covering the hole 21h and not covering the opening portion 24t. Thus, the cathode electrode 22c is connected to the n-type layer 21n of the second semiconductor layered body 21e via the hole 21h. Further, in the light-emitting device 2, the cathode electrode 22c is connected to the wiring of the wiring substrate 90.

Next, operations and effects of the light-emitting device according to the present embodiment will be described below.

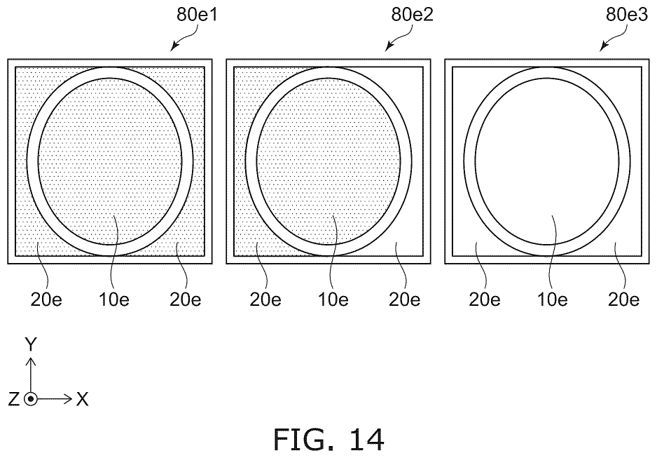

FIG. 14 is a top view illustrating operations according to the present embodiment.

In FIG. 14, lit portions are indicated by hatching.

As illustrated in FIGS. 12 and 13, in the light-emitting device 2 according to the present embodiment, the first portion 10e of each of the light-emitting elements 80e can be lit, as in the light-emitting device 1 according to the first embodiment. In addition to this, in the light-emitting device 2, because the p-type layer 21p of the second semiconductor layered body 21e is connected to the anode electrode 22a and the n-type layer 21n is connected to the cathode electrode 22c, the second portion 20e can be lit independently of the first portion 10e and the second portions 20e can be lit independently of each other.

Thus, two second portions 20e of each of the light-emitting elements 80e can be lit when the adjacent light-emitting element 80e is lit and can be unlit when the adjacent light-emitting element 80e is unlit. This can make it possible to select whether light propagation in the lateral direction is occur or not in accordance with the lit or unlit state of the adjacent light-emitting element, and thus contrast can be improved in the light-emitting device 2.

This will be described more specifically with reference to FIG. 14.

A case will be described in which three light-emitting elements 80e arrayed along the first direction X are referred to as a light-emitting element 80e1, a light-emitting element 80e2, and a light-emitting element 80e3. The light-emitting elements 80e1 and 80e2 are lit, and the light-emitting element 80e3 is unlit.

For the light-emitting element 80e1, the first portion 10e and the two second portions 20e are all lit. For the light-emitting element 80e2, the first portion 10e is lit. In the two second portions 20e, the second portion 20e disposed on the light-emitting element 80e1 side is lit, and the second portion 20e disposed on the light-emitting element 80e3 side is unlit. In the light-emitting element 80e3, all of the first portion 10e and the two second portions 20e are unlit.

This can make it possible to further increase the intensity of light in the lit light-emitting elements 80e, suppress occurrence of dark line between the lit light-emitting elements 80e, and improve the contrast between the lit light-emitting element 80e and the unlit light-emitting element 80e.

When the light-emitting element 80e3 is lit at a lower luminance than the light-emitting element 80e1 and the light-emitting element 80e2, the second portion 20e of the light-emitting element 80e2 disposed on the light-emitting element 80e3 side may be unlit, may be lit at about the same luminance as the light-emitting element 80e3, or may be lit at an intermediate luminance between the luminance of the light-emitting element 80e2 and the luminance of the light-emitting element 80e3. The configuration, operation, and effects of the present embodiment other than those described above are the same as those of the first embodiment.

Each of the above-described embodiments and modified examples is an example embodying the present invention, and the present invention is not limited to these embodiments and modified examples. For example, in each of the above-described embodiments and modified examples, those in which some of the components are added, omitted, or changed are also included in the present invention. The above-described embodiments and modified examples can be implemented in combination with each other. For example, the modified examples of the first embodiment may be combined with each other, or each of the modified examples of the first embodiment may be combined with the second embodiment.

What is claimed is:

1. A light-emitting device comprising:
a wiring substrate; and
a plurality of light-emitting elements, each having a rectangular shape in a top view, the light-emitting elements being arrayed on the wiring substrate along a first direction, wherein:
the light-emitting elements each comprise:
a first portion comprising a first semiconductor layered body, and an electrode connected to the first semiconductor layered body, and
a plurality of second portions disposed on either side of the first portion in the first direction, and each comprising a second semiconductor layered body, and a reflective layer connected to the second semiconductor layered body, and
the first portion comprises a first length section in which a length of the first semiconductor layered body in the first direction is a first length, and a second length section in which a length of the first semiconductor layered body in the first direction is a second length shorter than the first length.

2. The light-emitting device according to claim 1, wherein:
in the top view, the light-emitting elements each have a pair of sides extending in the first direction and a pair of sides extending in a second direction orthogonal to the first direction, and
the first length section is located at a center of the first portion in the second direction.

3. The light-emitting device according to claim 1, wherein:
in the top view, the light-emitting elements each have a pair of sides extending in the first direction and a pair of sides extending in a second direction orthogonal to the first direction, and
a third length in the second direction at a first position in the first direction of the first semiconductor layered body is longer than a fourth length in the second direction at a second position in the first direction of the first semiconductor layered body.

4. The light-emitting device according to claim 3, wherein:
the first position is a center of the first portion in the first direction.

5. The light-emitting device according to claim 3, wherein:
the first length is a maximum length of the first semiconductor layered body in the first direction,
the third length is a maximum length of the first semiconductor layered body in the second direction, and
the first length is shorter than the third length.

6. The light-emitting device according to claim 1, wherein:
a shape of the first portion in the top view is a circular shape.

7. The light-emitting device according to claim 1, wherein:
a shape of the first portion in the top view is an elliptical shape.

8. The light-emitting device according to claim 1, wherein:
a shape of the first portion in the top view is a polygonal shape.

9. The light-emitting device according to claim 1, wherein:
in the top view, one of the second portions is positioned at each of four corners of each of the light-emitting elements.

10. The light-emitting device according to claim 1, wherein:
in the top view, one of the second portions is positioned on each of both sides of the first portion in the first direction.

11. The light-emitting device according to claim 1, wherein:
the second portions each comprise an electrode connected to the second semiconductor layered body.

12. The light-emitting device according to claim 1, wherein:
in the top view, the light-emitting elements each have a pair of sides extending in the first direction and a pair of sides extending in a second direction orthogonal to the first direction, and
the light-emitting elements are arrayed in a matrix along the first direction and the second direction.

13. The light-emitting device according to claim 1, further comprising:
a light-transmissive member on which light emitted from one or more of the light-emitting elements is incident.

14. The light-emitting device according to claim 1, further comprising:
a covering member disposed between the light-emitting elements.
